(19) United States
(12) Patent Application Publication
(10) Pub. No.: US 2016/0064588 A1
(43) Pub. Date: Mar. 3, 2016

(54) CONCENTRATOR LENS FOR DIRECTING LIGHT TO A PHOTOVOLTAIC TARGET OR MIRRORED SURFACE AND A DYNAMIC WINDOW APPARATUS UTILIZING THE SAME

(71) Applicants: James B. PAULL, Andover, MA (US); Peter MORSE, Essex, MA (US)

(72) Inventors: James B. PAULL, Andover, MA (US); Peter MORSE, Essex, MA (US)

(21) Appl. No.: 14/835,118

(22) Filed: Aug. 25, 2015

Related U.S. Application Data
(60) Provisional application No. 62/042,993, filed on Aug. 28, 2014.

(51) Int. Cl. H01L 31/054; H02S 40/22; H02S 20/26; G02B 19/00; G02B 3/08

(52) U.S. Cl. CPC H01L 31/0543; G02B 19/0009; G02B 19/0042; G02B 3/08; H02S 20/26; H02S 40/22

(57) ABSTRACT

A lens device for concentrating light onto a photovoltaic target or mirrored surface is disclosed. The lens may be configured to receive and reflect at least a portion of incident light onto the photovoltaic target or mirrored surface, and pass a portion of incident light through the lens depending on the received light's particular angle of incidence. The lens may include a lens body having a first surface that extends away from a light incident base at generally a first acute angle relative to the base, and a collector surface extending from a distal end of the first surface toward the base at a second angle. The collector surface may include a photovoltaic target configured to receive a portion of light emitted from the base and to convert the received portion of light into electrical energy, or a mirrored surface configured to reflect light generally back to the origin.

### CROSS-REFERENCE TO RELATED APPLICATIONS

This application claims the benefit of U.S. Provisional Application Ser. No. 62/042,993, filed Aug. 28, 2014.

### FIELD

This invention generally relates to solar photovoltaic cells, and more particularly, to lenses that concentrate light onto a photovoltaic target or mirrored surface.

### BACKGROUND

Photovoltaic modules can utilize concentrator lenses, such as those formed into the shape of a parabolic compound concentrator (CPC), to direct light at a conductor or photovoltaic target that can convert light energy into electrical power. A CPC lens may be designed to direct light incident to its aperture to the photovoltaic target, provided the light arrives at a particular angular range known as the acceptance angle or acceptance angle range. The area about the acceptance angle is generally opaque to ensure light is reflected onto the photovoltaic target. Conversely, the CPC lens may pass light arriving outside of the acceptance angle using a transparent region of the lens.

While there is a small loss of power due to uncaptured light, this light can provide aesthetic benefits to the area adjacent the photovoltaic module. For instance, the uncaptured light may allow roof textures and other such surfaces otherwise obscured by the photovoltaic panel to be visible through the transparent regions.

### SUMMARY

The present disclosure comprises a photovoltaic module with an array of passively concentrating lenses integrated into a common upper sheet or pane. The pane may be constructed of a transparent material such as, for example, acrylic, polycarbonate, glass, a photovoltaic cell strip, and a clear dielectric coupling material. The pane may further include a backing to electrically and mechanically protect associated photovoltaic cells and associated wiring.

The concentrating lens can include geometries configured to direct a substantial amount of both direct and diffuse light incident on a vertical installation surface to a photovoltaic cell strip at the bottom of each concentrating lens. The geometry of the concentrating lenses may be further configured to direct light to the photovoltaic cell strips by total internal reflection (TIR) within the lens, without exceeding the critical angle for TIR. The lens geometry may yet further allow light external to a building or structure to pass through to the building's interior by having the photovoltaic module mounted or otherwise installed vertically on a surface of the building. The light incident on the vertically installed photovoltaic module at substantially horizontal angles may be outside of the acceptance angle range, thus allowing the light to pass through for illumination purposes. As will be appreciated in light of this disclosure, the lens geometries disclosed herein also allows lights, signs, building textures, and other color to be seen by observers at substantially horizontal or lower angles.

While a preferred embodiment is to use concentrating lens geometry in the general configuration of a compound parabolic concentrator (CPC), this disclosure is not necessarily limited in this regard. For example, non-parabolic curves and simple concentrating wedges or triangular prisms may also be suitable and are within the scope of this disclosure.

An embodiment employing generally triangular lenses may be preferable in certain applications. Like curved lenses such as CPC, a triangular lens with flat sides will also internally reflect incident light to an adjoining side of the triangular lens and a photovoltaic cell optically coupled to that surface. The angle of the reflective lens surface can be selected to optimize the angles of incident light that will allow intersection with the lens surface and such that the angle between a normal to the lens surface and the incident light is greater than the critical angle for total internal reflection for the lens material and air.

Triangular lenses may require more surface area of photovoltaic cells than curved lenses such as CPCs, but may have other advantages. A wider angle of acceptance may be obtained, flat surfaces may be easier to manufacture and mating with a transparency coupling structure or block for switch-ability between power and transparency modes may be more effective due to their simple geometry. The amount of polymer resin or glass needed for a triangular lens geometry may also be less than for a curved lens.

For curves that are not strictly parabolic, it may be preferable for achieving the best electrical performance to have lens curves that have tangents that continuously increase in angle with respect to the central axis of the lens from the aperture of the lens to its target. Concentrating lenses of a generally semi-circular profile may also be used.

In an embodiment, the form of the concentrating lens may be configured to use either mono-facial or bi-facial solar cells. If the lens is configured in the general shape of CPC for a bi-facial solar cell, a mirror film may be applied to the bottom of the lens such that light is reflected to the PV target which otherwise might be lost due to light striking the lens surfaces at angles less than the critical angle for total internal reflection (TIR).

Aspects of the present disclosure offer a number of advantages. For example, the concentrating photovoltaic module may be attached vertically to a wall or other surface of a building. The surface may be made of brick, concrete block, wood, metal sheathing or any other common building material. The concentrating lenses generate electricity from sunlight striking the module from higher angles (e.g., within the acceptance angle range), while the feature of the lenses that allows light to pass through at lower angles gives observers the appearance of the color and texture of the building material of the wall behind it, such as brick.

In another embodiment of the present invention, the module may be attached to the outside of a window, such as might be found in large glass panes in office and commercial buildings. As in the aspects discussed above, the module may generate electricity via light arriving at higher sun angles (e.g., within the acceptance angle range), but allows some diffuse sunlight at lower angles to enter the interior of the building. This can provide daylighting and reduce the electrical load for systems that provide artificial lighting within the building. This arrangement may also block direct sunlight from entering the building, which may reduce air conditioning loads, and also potentially eliminate the need for louvers to block the sun on building walls facing mid-day sun. In some cases, only a portion of a window may feature the concentrated photovoltaic module. For example, it may be desirable to dispose the concentrated photovoltaic module on an upper portions of a window, thus advantageously providing shading while still allowing building occupants to have unobstructed or otherwise “clear” view through the lower portions of the window.

In yet another aspect of the present disclosure, the concentrating photovoltaic module comprises the entire building window pane itself, providing all of the advantages mentioned above and saving the cost of a conventional window.

In yet another aspect, the concentrating photovoltaic module is attached on the inside of a conventional window (e.g., single-pane). The attachment and the efficiency of the concentrating photovoltaic module may be enhanced by optically coupling the concentrating photovoltaic module to the window. This may be done using clear dielectric gels, such as Dow Corning Sylgard 527, which can be formulated to provide sufficient adhesive strength to secure the module to the window, have enough “give” to allow for differential thermal expansion between the window and the module, and provide excellent optical clarity. Other adhesives may be suitable and are within the scope of this disclosure. Moreover, use of an adhesive such as a clear dielectric gel may provide a refractive index close to that of typical window materials such as glass or polycarbonate, and that of the concentrating photovoltaic module. Some such material may include polymers such as, for example, polymethyl methacrylate (PMMA), polycarbonate, or glass. The clear dielectric gel may provide enough resistance to flow to remain in contact between the concentrating module and the glass. Other coupling materials known in the industry may also be used to adhere and optically couple the concentrating module and the building's window.

In an alternative to the above aspects, the concentrating photovoltaic module may be incorporated inside double or triple pane insulating glass, as the concentrating photovoltaic module may be made thin enough for such use. If the module is made of polymer material, it may be heated or dried prior to insertion between panes to minimize water vapor that otherwise might emanate from the polymer material and condense between the panes.

This may provide a number of advantages. By having the concentrating photovoltaic module on the interior of a building, it is not exposed to the outside environment. If the module is constructed with polymers, it is protected from degradation from ultraviolet light and moisture.

Further, in some aspects, the concentrating photovoltaic module may use small blocks of concentrating lenses or lens blocks that are applied to the interior of a building's window in tile-like fashion. A concentrating lens block, as generally referred to herein, refers to a plurality of elongated concentrating lenses joined to a contiguous outward pane. A lens block may also include side walls for structural strength and for joining with adhesive or solvent welding to adjacent lens block to make a larger assembly or module. Lens blocks may then be electrically interconnected to produce voltages that are appropriate for use in low voltage direct current applications or to supply direct current to photovoltaic inverters in order to generate alternating current. Microinverters known in the industry, such as are made by Enphase may, for example, utilize voltages of 24 to 30 volts, with a power of about 200 watts, to produce grid-compatible alternating current. The window application of concentrating modules may be sized and the lens blocks interconnected in such a way so as to produce DC electricity compatible with these microinverters.

To assure ease of application, the coupling medium, such as a silicone gel, may be pre-applied to the flat surface of the lens block. The coupling medium may then be temporarily protected by the use of a release liner film, such as a thin film of PET (polyethylene terephthalate). Just before application to the inside of a window, the release liner may be peeled off.

The application of an individual lens block may be further enhanced by employing a tool that substantially eliminates the entrapment of air bubbles between the interior of the window and the coupling medium. The application tool, as will be described further in the description below, as it is engaged, slightly bends the lens block such that it makes the front of the lens block into a convex curve. An edge of the lens block at the beginning of the curved surface may be placed in contact with the interior of a window. Then as the tool is disengaged, the lens block may gradually flatten out, progressively contacting the coupling medium with the window from the initial to the distal edge of the lens block, squeezing out air that might otherwise be trapped.

In one specific example, the lens blocks may be as small as 50 mm on a side or as large as 800 mm, depending on a desired application. As described above, individual lens blocks can be joined together to form a larger photovoltaic device, such as a photovoltaic module. By using relatively small blocks, the concentrating module can be made to closely fit the dimensions of a window, taking advantage of window area that otherwise might not produce electricity.

In yet another aspect of the present disclosure, the concentrating module can be used as a cover for a sign. The angled lenses can provide electrical power for LED or other sign lighting, and the sign and its lights can be seen through the module from the point of view of an observer.

In still yet another embodiment of the disclosure, individual or small groups of blocks of lenses assembled with PV strips can be incorporated with electrical circuitry, such as buck-boost circuits, to supply an output voltage to charge portable electronic devices such as cell phones and laptop computers. These lens blocks or groups of lens blocks can be applied to the interior of windows or external vertical surfaces by suction cups or suction tape, for example, or merely placed in an approximately vertical position either indoors or outdoors to receive light and produce charging current. To facilitate standing in a vertical position, brackets or feet, similar to what is sometimes used to support a picture frame, may be used.

And as the optics for a horizontally installed concentrating photovoltaic module are much the same as for a vertically installed concentrating photovoltaic module, a further aspect is for the angled lens module to be used in a flat or low-angle orientation. As an all-polymer module may be considerably lighter than conventional photovoltaic modules constructed of glass and aluminum, this may allow for modules to be used on flat commercial roofs where weight loading might otherwise be a consideration.

In still yet another aspect of the present disclosure, the previously described aspects can be further enhanced by an additional component that enables true transparency through a window on demand.

In the previously described embodiments, light is directed to the photovoltaic target by concentrating lenses that utilize total internal reflection. In practical application, the lenses are designed such that light within their acceptance angle range intersect with lens surfaces, such that the angle of intersection between the light path and a normal to the lens surface is greater than critical angle for total internal reflection. As is well known in optical science, the critical angle for total internal reflection is determined by the refractive indices of both the lens material and air according to Snell's Law.

In this aspect, the concentrating photovoltaic module achieves transparency through the reflection of light inside the lenses being negated by bringing the lenses in intimate contact with an optical structure that is substantially a negative form of the concentrating lens block positive profile. To effect transparency, the surface of the negative optical structure may comprise a transparent material with a similar refractive index and with a surface tension with respect to that of the material of the concentrating lenses, such that when positive and negative, are brought into contact the positive and negative surfaces optically couple the two parts. The effect of this optical coupling substantially eliminates any difference in refractive indices between the lens block and the transparency coupling block, and by doing so, eliminates the total internal reflection that would otherwise occur. By joining the positive and negative together, the combination essentially becomes a planar monolithic structure similar to a pane of glass.

Similar to the concentrating lens block described above, the optical structure may be a mirror or negative of the concentrating lens block. This mating structure may be referred to as a transparency coupling block.

The narrow strips of photovoltaic cells can remain embedded in the monolithic structure, and limit the passage of light to the extent of the surface area they represent. In practical application with lenses with generally curved surfaces, for example, this may represent 30 to 40% of the surface area of a window. With wedge shaped, triangular lenses, or generally curved lenses having at least one generally flat surface, however, the photovoltaic cells may be oriented flat or approximately flat with respect to a window, and since photovoltaic cells are typically only 150 to 200 microns thick, and even less for thin film cells, in that orientation they present very little obstruction to transparency from the point of view of an observer. Even with the geometry of curved lenses, because the PV strips are so narrow, their appearance is greatly diminished or even eliminated to an observer at a distance from a window.

For practical reasons, the transparency coupling structure may not be a perfect negative of the concentrating lens block. For example, space may be allowed to accommodate the photovoltaic cell and its wiring connections at the bottom of the concentrating lenses. Also, the negative may forgo contact with the shorter, lower surface of curved concentrating lens to allow for relative horizontal movement between the two components. Also, the concentrating lens block may have a shelf or lip at its bottom where the negative component and allow for relative horizontal movement.

The concentrating lens block positive and the transparency coupling block may be brought together in a number of different ways. For example, electromagnets may be embedded in or placed on the concentrating lens block and the negative coupling block. Wires may be used to electrically connect the electromagnets of individual or groups of window tiles and may be routed through the window frame and connected to a controlling system, such as a building automation system.

Another way the components may be brought into contact to achieve transparency is by using mechanical components such as linkages. For example, four-bar linkages associated with the practice of kinematics may be used to bring together individual or groups of lens blocks and their respective transparency coupling blocks. The linkages may be driven by small motors or solenoids located, for example, in the window frame or window perimeter. Further, linkage, components may be made from transparent materials, such as clear plastic so as to reduce any effect on transparency. As will be appreciated in light of this disclosure other mechanical mechanisms may be used to engage and disengage the two components.

Yet another way transparency may be actuated is by using differential air pressure. The lens block and its respective transparency coupling block may be hermetically isolated from the interior of an insulating glass window unit. This may be achieved by sealing a lens block or a group of lens blocks to their respective transparency blocks with a clear plastic film or membrane, attached to the blocks with an adhesive. A tube or conduit may then lead from the enclosed space formed by this membrane and the block components to a pneumatic pressure device such as a fan or vacuum pump. This fan or vacuum pump may be in a centralized location within a building or may be incorporated on or near an insulated glass window frame itself. Furthermore, a second tube or conduit may be from the pneumatic pressure device to the interior of an insulating glass unit that is not occupied by the membrane structure of the lens blocks and their respective transparency blocks.

The pneumatic pressure device may be designed to create a difference in air pressure between the hermetically sealed membrane structure enclosing the blocks and the remaining space on the inside of an insulating glass unit. It may also be configured to ensure that the net air pressure on the interior of an insulating glass unit remains constant, although allowing for a differential pressure between the internal components. In this way, pressure differences between the inside and outside the window unit may be avoided, along with the mechanical issues that might otherwise arise.

As in previous aspects, the pneumatic system may control all window tiles within an insulating glass unit or may control individual tiles or groups of tiles such as rows or columns within a window.

Still yet another aspect of the present disclosure comprises the concentrating lens blocks of the previous aspects and the transparency coupling blocks of the aspect described above modified to enable yet another useful function.

It may be useful in certain regions of the world to provide a further means of controlling solar gain and buildings. This may be the case, for example, in the Middle East or the US Southwest.

The concentrating lens blocks with a photovoltaic strips described in the previous aspects are effective in directing most incoming light to the photovoltaic target. When light strikes the photovoltaic cells, its energy is either converted into electricity or heat. The heat thus generated is dissipated by conduction and radiation to both the outside and the inside of the building. This is similar to what achieved by smart windows such as electrochromic or thermochromic windows. These technologies absorb light through their tint and dissipate heat in a manner similar to that described above.

Solar heat gain through windows can be greatly reduced if incident light is reflected back out rather than being absorbed by the window. The concentrating lens block design of the present disclosure may be modified to reflect most all light back out from the window. To do this, the photovoltaic cells at the bottom of the lenses may be replaced by reflective film or mirrors. However, if the geometry of the bottom of the concentrating lens is flat, reflective film or mirrors may cause unacceptable glare or reflection, creating problems for example, aircraft navigation. This may be avoided by modifying the bottom surface of the concentrating lenses. For example, instead of the flat surface described in the above embodiments, the bottom of the concentrating lenses may be curved to effect scrambling of light reflected out of the concentrating lenses.

Further, for such concentrating lens blocks of approximately triangular shape, it may be useful to slightly curve surfaces that would otherwise be flat to ensure light passing through the lenses gets refracted in different degrees thus scrambling the light and providing visual privacy for occupants.

### BRIEF DESCRIPTION OF THE DRAWINGS

These and other features and advantages of the present disclosure will become apparent to those skilled in the art upon reference to the following written description and accompanying drawings.

FIG. 1 shows a cross-sectional view of angled concentrating lens geometry, in accordance with an embodiment of the present disclosure.

FIG. 2 shows a cross-sectional view of angled concentrating lens geometry with various light paths, in accordance with embodiments of the present disclosure.

FIG. 3 shows a cross-sectional view of angled concentrating lens geometry for use with bi-facial solar cells, in accordance with an embodiment of the present disclosure.

FIG. 4 shows a cross-sectional view of a concentrating lens with a photovoltaic cell with conductors outside the path of light, with lens and cell joined by an intermediate coupling medium, in accordance with an embodiment of the present disclosure.

FIG. 5 is a perspective view of an assembly including angled concentrating lenses, in accordance with an embodiment of the present disclosure.

FIG. 6 is a perspective view of a block of angled concentrating lenses with side walls, in accordance with an embodiment of the present disclosure.

FIG. 7 shows a cross-sectional view of a concentrator module installed on an outside surface of a building such as a wall or window, in accordance with an embodiment of the present disclosure.

FIG. 8 is a cross-sectional view of a concentrator module installed to the inside of a building's window, in accordance with an embodiment of the present disclosure.

FIG. 9 is a cross-sectional view of a concentrator module installed in the interior of multiple-pane insulating glass, in accordance with an embodiment of the present disclosure.

FIG. 10 shows a perspective view of a concentrating module lens block with optical coupling and adhering medium pre-applied, in accordance with an embodiment of the present disclosure.

FIG. 11 depicts a method for applying individual concentrating module lens blocks to a window surface, in accordance with an embodiment of the present disclosure.

FIG. 12 shows a perspective view of a lens block window view in juxtaposition to an associated transparency block, in accordance with an embodiment of the present disclosure.

FIG. 13 shows a cross-sectional view of a lens block with compound parabolic lenses separated from its associated transparency block, in accordance with an embodiment of the present disclosure.

FIG. 14 shows a cross-sectional view of a lens block with compound parabolic lenses in contact with its associated transparency block, in accordance with an embodiment of the present disclosure.

FIG. 15 shows cross-sectional view of a lens block with triangular prismatic lenses separated from its associated transparency block.

FIG. 16 shows a cross-sectional view of a lens block with triangular prismatic lenses in contact with its associated transparency block, in accordance with an embodiment of the present disclosure.

FIG. 17 shows a cross-sectional view of a lens block with a supporting structure for its associated transparency block, in accordance with an embodiment of the present disclosure

FIG. 18 shows a cross-sectional view of a lens block with a membrane connecting to its transparency block, in accordance with an embodiment of the present disclosure

FIG. 19 shows a partial three-dimensional view of a lens block, an associated transparency block, and a connecting membrane in the form of a bellows, in accordance with an embodiment of the present disclosure.

FIG. 20 is a schematic representation of membrane connected lens block and transparency block inside an insulated glass window resulting from performing a method that pneumatically engages respective components, in accordance with an embodiment of the present disclosure.

### DETAILED DESCRIPTION

A photovoltaic device for concentrating light onto a photovoltaic target is disclosed herein. The photovoltaic device may include a lens configured to receive and reflect at least a portion of incident light onto the photovoltaic target and pass a portion of received incident light through the lens depending on the received light's particular angle of incidence. In particular, the photovoltaic device includes a base having a light incident interface, and a lens extending from the base and having a lens body. The lens body may include a first surface extending away from the base at generally a first acute angle relative to the base, and a collector surface extending from a distal end of the first surface toward the base at generally a second angle. The collector surface may include a photovoltaic target configured to receive a portion of light emitted from the base and convert the received portion of light into electrical energy.

In one specific example, a window apparatus for use in buildings and other structures may be configured with or otherwise retrofitted with a plurality of photovoltaic devices disclosed herein. This example may be accurately described as a window-mounted photovoltaic device. The window-mounted photovoltaic device may include a plurality of concentrating lenses extending from a common light incident interface. Each lens can include a lens body that extends from the common light incident interface at generally a first acute angle relative to the base, and a collector surface extending from a distal end of the first surface toward the base at generally a second angle. The collector surface may include a photovoltaic target configured to receive a portion of light emitted from the base and convert the received portion of light into electrical energy. As will be appreciated, the window-mounted photovoltaic device can provide transparency similar to that of a pane of glass.

In another specific example, a window apparatus for use in buildings and other structures may be configured with or otherwise retrofitted with a plurality of non-photovoltaic concentrating lens devices having at least one mirrored surface. The non-photovoltaic concentrating lenses may, in a sense, reject a portion of incident light to reduce air conditioning loads within a building. This example may be accurately described as a window-mounted thermal management device. The window-mounted thermal management device may include a plurality of concentrating lenses extending from a common light incident interface. Each lens can include a lens body that extends from the common light incident interface at generally a first acute angle relative to the base, and a collector surface extending from a distal end of the first surface toward the base at generally a second angle. The collector surface may include a mirrored surface configured to receive a portion of light emitted from the base and reflect the light generally back towards the origin. In some embodiments, a window-mounted device may include both photovoltaic (e.g., converts light into electrical power) and non-photovoltaic concentrator lenses (e.g., rejects a portion of light by reflecting the same generally back towards the origin).

General Overview

As previously discussed, CPC lenses can direct all light wavelengths within its acceptance angle to a photovoltaic cell positioned at the bottom of the lens. However, when such lenses are mounted to windows, and other building surfaces, they make the window opaque over the range of the acceptance angle.

Thus, in accordance with an embodiment of the present disclosure, a photovoltaic device that may be window-mounted and configured to provide transparency in regions configured to receive incident light, and convert the same into electrical energy, is disclosed herein. Moreover, the photovoltaic device disclosed herein may pass at least a portion of incident light through each concentrating lens to illuminate internal building spaces, or allow objects otherwise obscured by the photovoltaic device to be visible.

Numerous advantages will be apparent in light of this disclosure. For example, the photovoltaic device may be window-mounted and provide transparency sufficient to allow building occupants to view objects external to the building. Likewise, a photovoltaic device mounted on a building façade may provide visibility of the brick or other material otherwise obscured by the photovoltaic device. In addition, the photovoltaic device disclosed herein advantageously collects high-angle sunlight to generate electrical power, and thus blocks the same from entering a building. Also, as previously discussed, non-photovoltaic lenses (e.g., lenses without a photovoltaic target) may reject a portion of incident light to reduce air conditioning loads within a building. Still further, the photovoltaic device disclosed herein provides an adjustable degree of external and internal transparency when mounted to or otherwise integrated into a window. The photovoltaic device may also provide switchable transparency and translucency to provide privacy for building occupants.

### Example Lens Assemblies

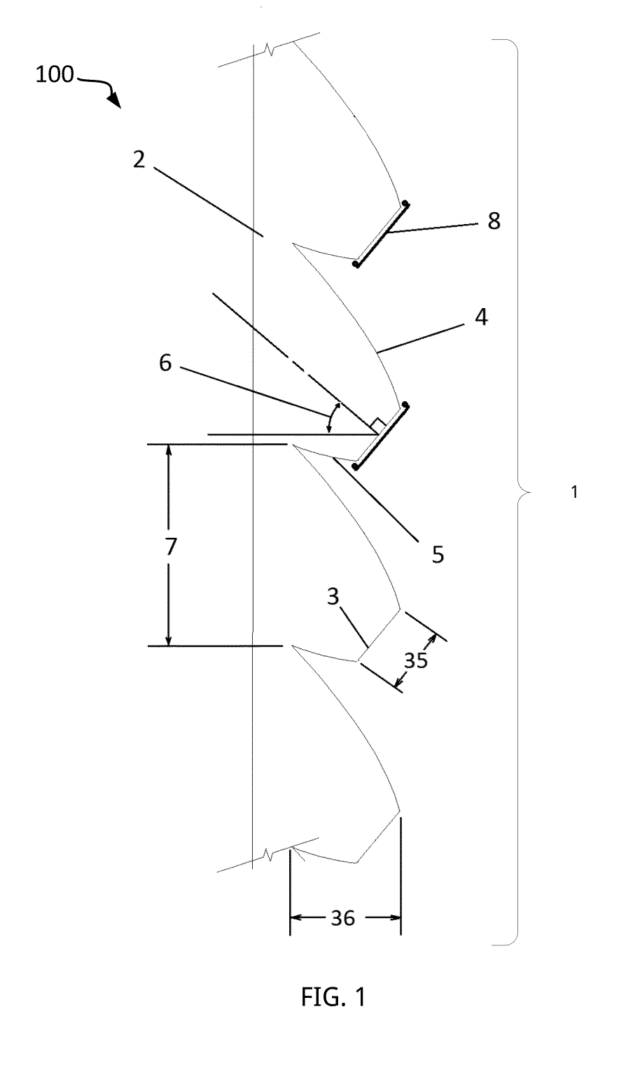

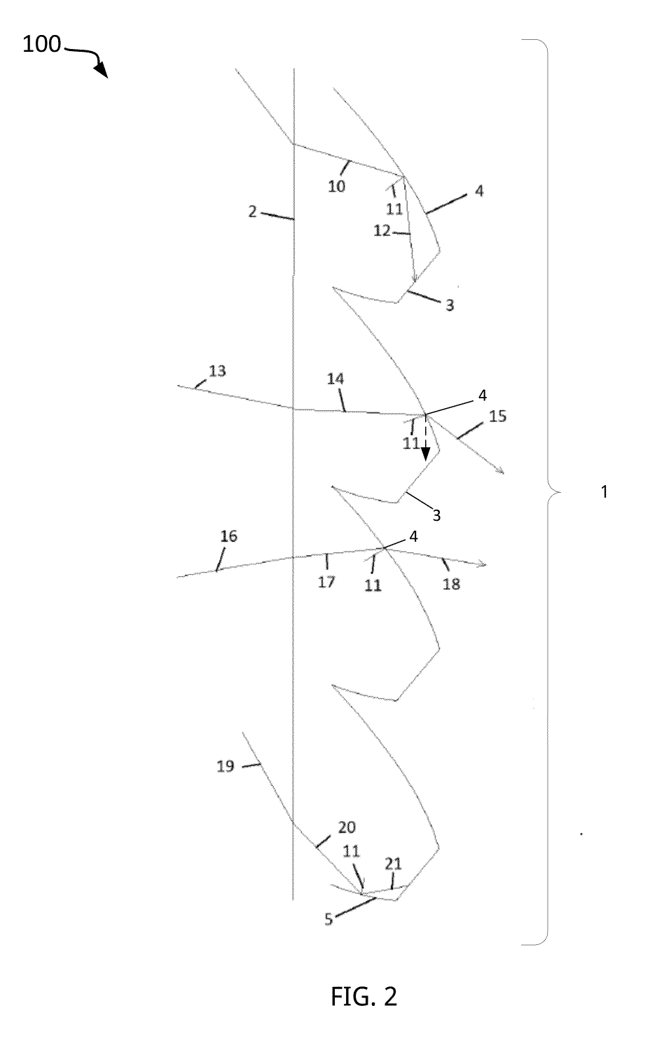

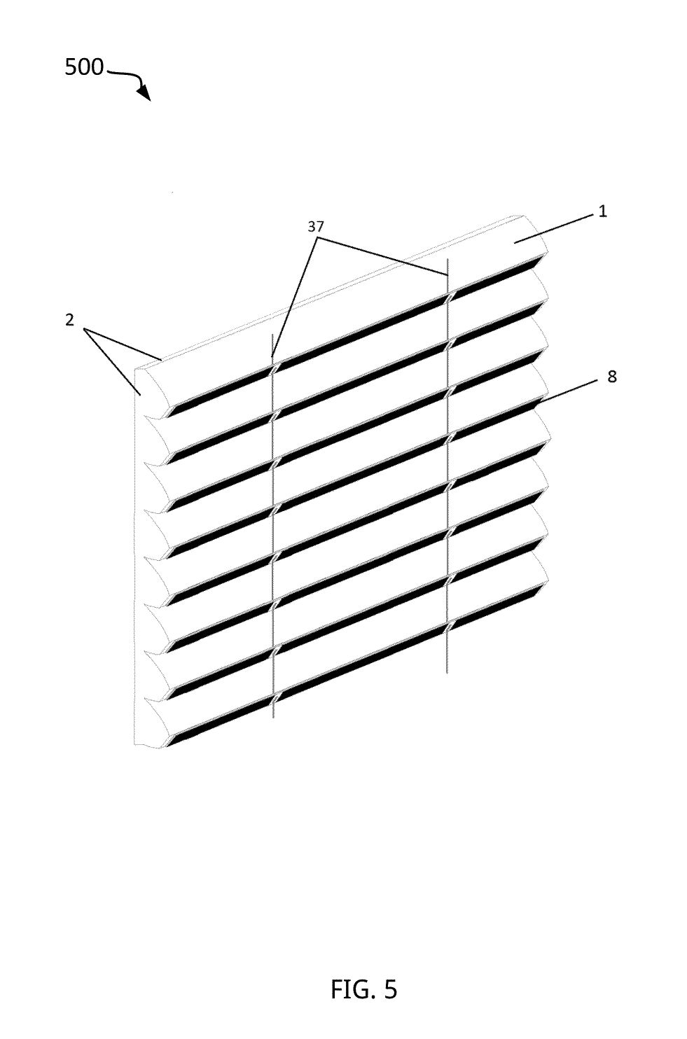

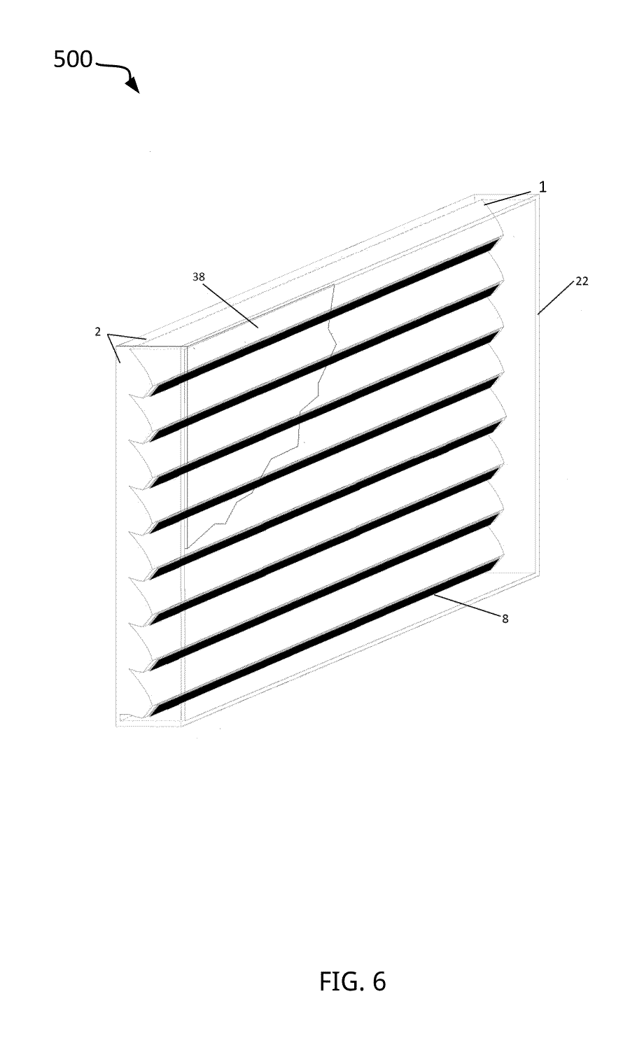

Now turning to the Figures, FIGS. 1 and 2 show cross-sectional representations of an example photovoltaic assembly 100 or device with a plurality of concentrating lenses, according to an embodiment of the present disclosure. As shown, each concentrating lens 1 is elongated normal to the plane of the drawing which will be further seen in FIGS. 5 and 6. FIG. 1 illustrates a plurality of concentrating lenses 1 integrally joined to a contiguous outward pane 2. The contiguous outward pane 2 may serve as a structure to hold the individual concentrating lenses 1 together.

As light passes from one medium with a first index of refraction to a second medium with a different index of refraction, it is refracted. If light passes from a medium with a lower index of refraction to one with a higher index of refraction, the light is refracted to the normal. Conversely, if light passes from a higher to a lower index of refraction, the light is refracted away from the normal. Snell's Law determines the amount the light is refracted by the equation n₁ sin_{θ}=n₂ sin θ₂ where n₁=index of refraction of the first medium and n₂=index of refraction of the second medium.

With Snell's law, as the angle of incidence θ₁ increases, the angle of refraction approaches 90 degrees. The angle of incidence θ₁ that produces an angle of refraction θᵣ of 90 degrees is the critical angle θ_{c} which may be determined by the equation:

θ_{c}=sin⁻¹(n₂/n₁).

Increasing the angle of incidence θ₁ to greater than the critical angle θ_{c} results in total internal reflection (TIR). When TIR occurs, the angle of incidence θ₁ is equal to the angle of reflection θ_{F}.

Thus in view of Snell's law, an “interface” thus exists where light may propagate from one medium with a first index of refraction to a second medium with a second index of refraction. In the present disclosure these principles are embodied in the light incident interface 2, and other similar interfaces, disclosed herein.

For clarity, only a small section of a photovoltaic assembly is illustrated in FIG. 1. It may be appreciated that a plurality of such photovoltaic assemblies may be employed on a given module in application, e.g., 20-500, which may be dictated by power requirements.

Each concentrating lens 1 with an elongated shape and the contiguous outward pane 2 generally as shown in FIGS. 1-4 in and may be made from transparent polymer resin material. Reference to a concentrating lens 1 may be understood as any lens that is capable of directing light of a given wavelength or range of wavelengths to a given location, and should not be construed as limited to the lens configuration shown. Transparent polymer resin material may be understood as a material herein that transmits light sufficient for the photovoltaic material (described more fully below) to absorb light and generate electrons. For example, transparent material herein may transmit 50% or more of visible light, including all values and increments between 50-100%. For example, such materials may include acrylic, polycarbonate, polyethylene terephthalate (PET), cellulosic esters, polystyrene, nylons, poly-4-methyl-1-pentene, just to name a few. The transparent material may also include those polymeric materials that are primarily amorphous (e.g. greater than 50% amorphous content) and which have a glass transition temperature (Tg) of above about 50 degree. C. The transparent materials contemplated herein may also include glass.

The contiguous outward plane may accurately described as a base having light incident interface. The concentrating lens may extend from the base and have a lens body. The lens body may include a first surface 4 extending away from the base at generally a first acute angle relative to the base, and a collector surface 3 extending from a distal end of the first surface toward the base at generally a second angle. The intersection of the first surface 4 and the collector surface 3 may form an apex. The collector surface may include a photovoltaic target 8 configured to receive light reflected from the first surface 4 and to convert the received light into electrical energy. The photovoltaic target 8 may be replaced by a mirrored surface, with that mirrored surface reflecting incident light back generally towards its origin. As should be appreciated, this prevents a portion of light from entering a building or other structure which can reduce air conditioning loads and increase occupant comfort. This mirrored surface is not limited to a particular lens shape and is equally applicable to other embodiments of a concentrating lens disclosed herein.

The concentrating lenses 1 constructed of polymer material may be individually formed using injection molding, extrusion or casting, and then subsequently joined to the contiguous outward pane 2 by solvent welding or transparent adhesives. Solvent welding may be accomplished in the case of lenses 1 and contiguous outward pane 2 made from acrylic or polycarbonate, for example, by using methylene chloride or Weld-On 4 made by the IPS Corporation. Transparent adhesives that may be used include 3-M Corporation 3141 optically clear laminating adhesive and UV-curable AB-1 made by Nextgen Corporation.

An advantage of making the concentrating lenses 1 and contiguous outward pane 2 separately is that they can be made from different materials. For example, the concentrating lenses 1 may be made from acrylic for its optical clarity and low cost, while the contiguous outward pane 2 may be made from polycarbonate with low flammability.

Alternatively, the concentrating lenses 1 and contiguous outward pane 2 may be injection molded, extruded or cast as one piece. This may also allow for other features to be incorporated in the molding or casting, such as side walls to give structural support, attachment point for electrical connections and holes or indentations in side walls to facilitate the use of installation tools described further below.

One advantage of the angled concentrating lenses 1 positioned in a vertical plane is their ability to harvest a very large percentage of incident light in order to convert it to electrical energy. An additional advantage of this approach is the angled concentrating lenses allow a certain amount of otherwise unproductive sunlight to pass through the concentrating lenses, allowing daylighting and architectural lighting effects, which can be pleasing to building occupants.

To do this effectively requires careful specification of the angles and geometry of the concentrating lenses.

FIG. 2 shows four examples of possible paths of light through the concentrating lenses 1 as a context for illustrating how the practical effect of the particular lens geometries disclosed herein. Light ray 9 represents light impinging on contiguous outward pane 2 at a relatively high angle with respect to the horizontal. Upon reaching the contiguous outward pane 2 it is refracted to a more horizontal angle, represented by ray 10, due to the higher refractive index of the material of the contiguous outward pane 2 and the concentrating lens 1, which in the example case of acrylic or PMMA is 1.5. Upon intersecting the side 4 of the concentrating lens 1, the light reflects internally because the angle between ray 10 and a normal to a tangent to lens side 4 of the concentrating lens 1 is greater than the critical angle for total internal reflection, which in the example case of acrylic or PMMA would be approximately 41.8 degrees. And because incident ray 9 is within the acceptance angle of the compound parabolic curve of lens side 4, it strikes the bottom surface 3 of concentrating lens 1 and the photovoltaic cell strip 8 (or alternatively the mirrored surface) adhered to it.

Ray 19 also represents light from a high angle with respect to the horizontal. As in the above example, it refracts to a ray 20 with an angle closer to horizontal, internally reflects off of lens surface 5 to ray 21 and strikes the bottom 3 of concentrating lens 1.

Ray 13 represents light impinging at an angle slightly above horizontal. As before, it refracts to ray 14, which in turn intersects lens side 4. In this case, however, the angle with respect to a normal to a tangent to side 5 is less than the critical angle for total internal reflection, so ray 15 passes out of the concentrating lens 1 and does not reach the bottom 3 of the concentrating lens 1, even though the angle of incoming ray 13 is within the acceptance angle range for the compound parabolic curved side 4 of concentrating lens 1.

However, because ray 13 is within the acceptance angle for lens side 4, if maximum energy harvest is desired, a reflective film or reflective coating may be applied to lens side 4 so that the critical angle for total internal reflection issue will no longer apply and the light will be reflected to lens surface 3. If a reflective film or coating is applied to lens side 4, some or all of the additional benefit of some light passing through the lens for daylighting, or the ability to have internal lights to be seen through the lens, will be lost.

Ray 16 represents light impinging the surface of contiguous outward pane 2 at an angle below the horizontal. It refracts to ray 17 and then intersects lens surface 4. Because the angle of intersection is less than the critical angle and also may be out of the acceptance angle range for parabolic curved lens surface 4, it passes through the concentrating lens 1 as ray 18.

For practical application, it may be desirable to ensure that as much sunlight with the potential to produce significant power reaches the photovoltaic cell strip 8 via the concentrating lens 1. The range of angles to include sunlight with this capability is taken from a 15 degree elevation above horizontal to directly overhead, or 90 degrees above horizontal. 15 degrees is chosen as the lower limit of the useful elevation of sunlight as at that elevation, the sun's azimuth with respect to a generally southerly orientation of a window in a northern hemisphere winter is large enough such that the contribution of sunlight due to the cosine effect or projected surface area of the photovoltaic module is minimal. Moreover, for half of the year in the northern hemisphere, sunlight at an elevation of 15 degrees is mostly behind a southerly facing window. Other ranges of angles will be apparent in light of this disclosure based on the particular hemisphere/location of the photovoltaic assembly 100.

It also may be advantageous, with the additional benefits of daylighting, signage and architectural effects in mind, to have most or all of light incident below an angle of 15 degrees below the horizontal to pass through the concentrating lenses 1.

As noted above, lens sides 4 and 5 may be parabolic curves, with the focus for parabolic curve 5 at or near the intersection of lens side 4 and lens bottom 3, and with the focus of the parabolic curve of lens side 4 at or near the intersection of lens side 5 and lens bottom 3. Curves similar to purely parabolic curves may also be used, and may have curves that have tangents that continuously increase in angle with respect to the central axis of the concentrating lens 1 along the path of the light entering the lens. Triangular or wedge-shaped lenses may also be used. Semi-circular lenses formed on the outside of contiguous pane 2 may be used as well. These are but a few example lens shapes and others will be apparent in light of this disclosure.

Angle 6 in FIG. 1 is the angle of the center axis of the concentrating lens 1 from the horizontal. To achieve the performance objectives stated above, angle 6 in one embodiment is 36 degrees. In some cases, angle 6 may be within a range of 24 to 45 degrees from the horizontal.

The shape of the parabolic curves for lens side 4 and 5 is generally defined by the acceptance angle for a compound parabolic concentrator. It may be appreciated that the shape of non-strictly parabolic curves may be similarly defined. For this embodiment, a CPC acceptance half angle of 27 degrees interior to the lens defines the parabolic surface of lens side 4, with a similar geometry for lens side 5. In one embodiment, the half angle is within a range of 17 degrees to 41 degrees. The curvature of lens side 4 and lens side 5 may not have to be exactly the same, and may differ from each other to facilitate a desired lens aperture width. Also, the full CPC or similar curves may be truncated to increase aperture size, enhance light passage at low angles and reduce the amount of polymer resin or glass required.

The particular height 7 of the horizontal aperture is a function of the acceptance half angle of the concentrating lens 1, the width 35 of the bottom 3 of the concentrating lens 1 and the thickness of the lens 36. In some cases, the ratio of horizontal aperture height 7 to the width 35 of the lens bottom 3 is 2.9 to 1. However, other ranges are within the scope of this disclosure. For example, the ratio may be from 2 to 3.75.

As optics are not adversely affected by the scale of the concentrating lens 1, other than for light attenuation as it passes through the lens, theoretically the lens thickness 36 is not limited. However thicker lenses require more polymer resin, resulting in higher cost and weight. Very thin lenses may require more precision in assembly and more manufacturing and assembly operations. In any event, the lens thickness 36 may be 0.16 inches (4 mm). In some cases, the lens thickness 36 may be a range from 0.08 to 0.6 inches (2 to 15 mm).

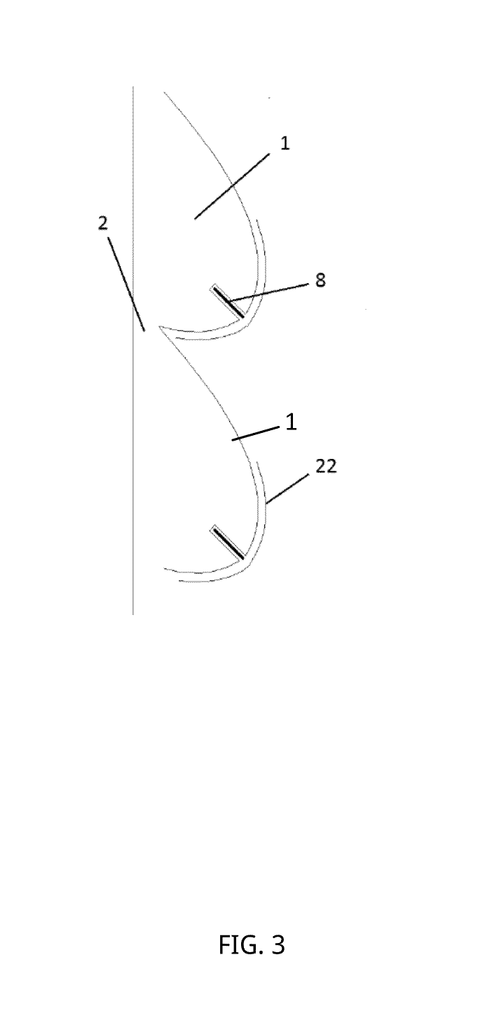

The embodiment described above is particularly well suited for concentrating lens designed for mono-facial photovoltaic cells. In an alternative embodiment, a CPC or similar lens designed for bi-facial cells may be used. FIG. 3 shows one such an example embodiment. As with the previous embodiment, this embodiment comprises a plurality of elongated concentrating lenses 1 integrally connected to a contiguous outward pane 2. The shape of the parabolic or similar curved sides of the concentrating lenses do not lead to a flat surface at the bottom of the lens as in the previous embodiment of FIGS. 1 and 2, but instead to a vertical target coincident with the central axis of the lens. The photovoltaic cell 8 is incorporated at the optical target in a slot in the bottom of the concentrating lens 1. The photovoltaic cell 8 is optically coupled to the concentrating lens 1 in a manner similar to the embodiments of FIGS. 1 and 2 discussed above. Light may be incident on both sides of the bi-facial cell, making full use of its electrical energy producing potential.

Because of its different, more rounded shape, the bi-facial concentrating lens 1 cannot depend entirely on total internal reflection, as light reaching the surface of the sides of the lens at its bottom may be outside the critical angle for total internal reflection. To prevent the escape of light from the lens, a reflective film may be adhered to the sides of the concentrating lens 1 or a mirror may be deposited on the lens surface.

For mono-facial concentrating lenses, a strip of photovoltaic material 8 at the bottom 3 of the concentrating lens 1 may be positioned along the bottom of the lens so as to receive the concentrated light. Reference to concentrated light may therefore be understood as light that has entered the lens assembly and is then directed to the bottom photovoltaic strip. The width of the photovoltaic strip may therefore be, for example, 75-130% of the width of the bottom 3 of the lens 1. To advantageously provide the removal of the cell electrical conductors out of the path of light, described below, the width of the cell may be 105% to 130% on the width of the bottom of the lens 3. As should be appreciated, ultimately, this width may be selected to optimize the efficiency of the photovoltaic strip when it comes to interaction with light photons and electron generation and production of electricity.

The photovoltaic material chosen may include a light-absorbing material to absorb photons and generate electrons via the photovoltaic effect. The photovoltaic material may be made from multi-crystalline or mono-crystalline silicon, for example. The photovoltaic strips may be cut from larger cells, such as 156 mm cells. Larger cells may scribed by a laser with scribes made at the desired width of the photovoltaic strips 8, each strip subsequently broken off from the larger cell. Alternatively, the photovoltaic strips 8 may be cut from a larger cell using, for instance, dicing saws.

The photovoltaic material may also include what may be described as a thin-film photovoltaic, which may be understood as inorganic layers, organic dyes and organic polymers deposited on a supporting substrate. For example, the thin film photovoltaic may include an inorganic material such as copper indium gallium di-selenide (CIGS). It may also include amorphous silicon thin-film photovoltaic materials. One may also use mono or polycrystalline silicon photovoltaic materials, depending on a desired configuration.

With either crystalline silicon or thin-film photovoltaic materials, the performance of the cells in the concentrating lens assembly may be further enhanced by placement of electrically conductive contacts on the photovoltaic cell. Photovoltaic cells generally have metallic conductors made from silver, copper or aluminum on both sides to carry away electrons generated by the photovoltaic effect. These conductors, known as fingers and busbars, are typically not capable of generating electricity themselves. The fingers and conductors on the upper, light receiving surface of the photovoltaic cell shade the cell from light that could otherwise produce electricity.

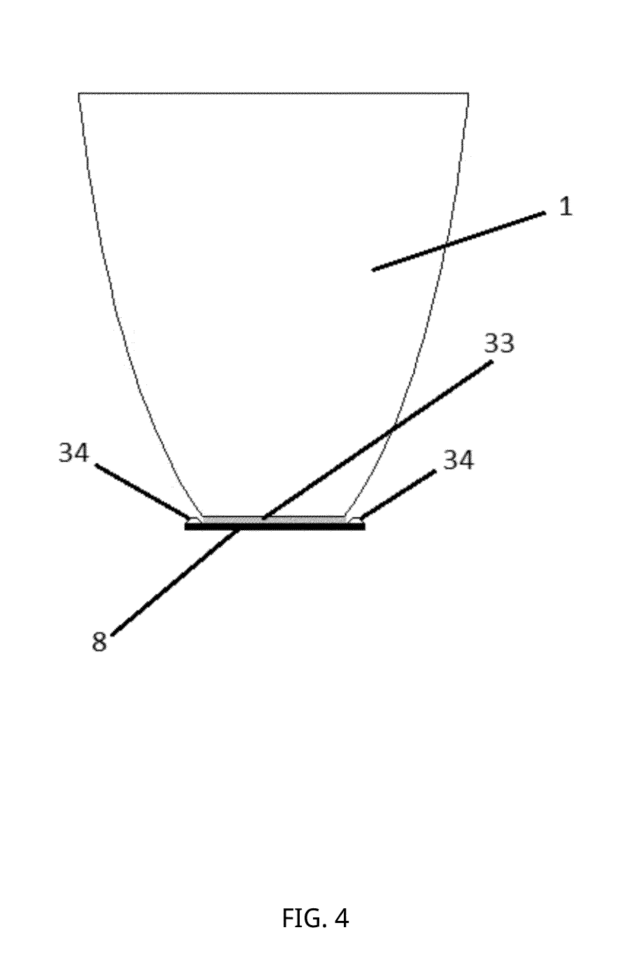

Turning attention to FIG. 4, an arrangement for removing a substantial amount of non-electricity producing conductor material from active cell surface is shown, in accordance with an embodiment of the present disclosure. As shown, an individual concentrating lens 1 in assembly with a photovoltaic cell strip 8, optically coupled to a concentrating lens 1 with a coupling medium 33.

FIG. 4 further shows that the conducting fingers 34 may be placed outside of the flat target surface 3 of the concentrating lens 1 so that they do not shade the active surface of photovoltaic strip 8. The elimination of this shading may allow as much as 6% or more current to be generated by the photovoltaic cell strip 8, thus increasing the efficiency and output of the solar module. Such placement of cell conductors out of the path of light are also equally applicable to concentrating lenses of various shapes and configurations (e.g., as shown in FIGS. 1 and 2), and not necessarily just to the angled lens configuration described and illustrated herein.

With respect again to FIG. 4, the coupling medium 33 may be a transparent gel or optically clear adhesive, for example. Light transmission through the gel or adhesive may be 50% to 100% over the wavelengths of incident light from 380 nanometers to 700 nanometers, for example. The thickness of the gel or adhesive may range from 0.001 inch to 0.010 inches, for example. Another parameter of the coupling gel or adhesive that may be important is its elasticity. Elasticity may be important in allowing differential thermal expansion between the concentrating lens 1 and the photovoltaic strip 8. Further, it may also be important for the coupling medium 33 to have an index of refraction close to or exceeding that of the material of the concentrating lens 1, in order to reduce loss of light due to reflection from the material interface. Yet another parameter is the adhesive ability of the coupling medium 33 to maintain bonding of the photovoltaic cell 8 to the concentrating lens 1, over changing conditions of temperature and humidity, particularly those of extreme degree. Still yet another parameter of the coupling medium 33 is its ability to make and maintain complete wetting or optical coupling of the surfaces of the concentrating lens and photovoltaic strip. One particular coupling medium 33 particularly well suited to meet the above-mentioned parameters is Dow Corning two-part Silicone gel Sylgard 527. In one embodiment, the coupling medium 33 is applied to include a thickness of approximately 0.003 inches.

In an alternative embodiment, coupling between the concentrating lens and the photovoltaic strip may be accomplished with a transparent liquid, such as mineral oil. In this embodiment, the liquid coupling medium can be encapsulated and contained using a reflective film wrapping around the concentrating lens and photovoltaic cell strip assembly, which may be attached to the sides of the concentrating lens using an optically clear adhesive.

FIG. 5 shows a perspective view of a lens block 500, which includes a plurality of elongated concentrating lenses 1 joined with a contiguous outward pane 2. The lens block 500 may also comprise photovoltaic strips 8 adhered to the concentrating lenses with a coupling medium 33. The photovoltaic cells 8 may be electrically interconnected, either in series or parallel, or a combination of the two, by wires 37 to produce the electrical output voltage and current desired for a particular application. Wires 37 may lead to terminals inside or outside of the lens block. Wires 37 may also lead to male and female plugs and sockets on the side walls, such as shown in FIG. 6, so that electrical interconnections may be made between individual lens blocks. The plugs and sockets may be designed such that the electrical plugs and sockets of one lens block insert into the plugs and sockets of an adjacent lens block when it is installed. The electrical interconnections may be such that the lens blocks themselves can be connected electrically either in series or in parallel.

FIG. 6 is another perspective of the lens block 500, which includes a plurality of concentrating lenses 1, a contiguous outward pane 2 and photovoltaic cell strips 8. Also shown are side walls 22 and a protective back cover 38.

The lens block side walls 22 provide structural strength, a mounting surface for electrical plugs and sockets and may have holes, grooves or indentations to assist in an installation on a window as described subsequently. The side walls 22 may also be joined to the side walls of other lens blocks using solvent welding or adhesives to make a larger assembly or module.

Back cover 38 is shown in FIG. 6 in partial view in order not to obscure detail below it; the back cover may extend over the entire back side of the lens block. Back cover 38 may be made from, for example, a polymer material or glass and may be attached to the side walls 22 using solvent welding or adhesives as may be appropriate. It may be opaque or clear depending on the effect desired. The back cover 38 may serve to protect the photovoltaic cells 8 and the wiring 37 from damage, and may add to the structural integrity of the lens block.

If a reflective film is adhered to the concentrating lenses 1, an alternative to back cover 38 may include adhering a solar photovoltaic module back sheet film to the back of the reflective film. Such solar back sheets may typically be constructed of a lamination of PET and fluoropolymer films.

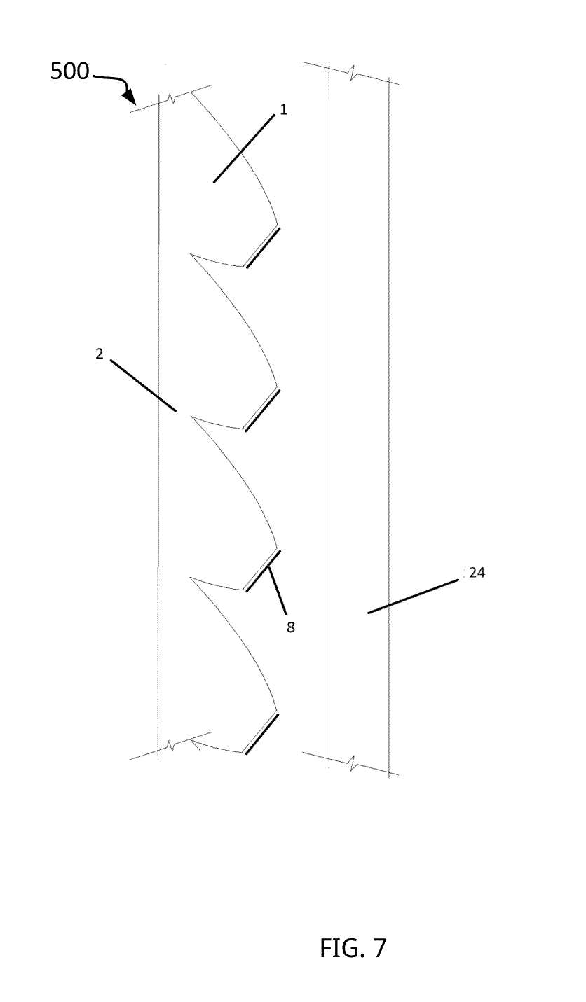

FIG. 7 shows a cross-sectional representation of the lens block 500 whereby the lens block assembly 500 is mounted exterior to a building's window. In this embodiment, electricity is generated by the photovoltaic cells 8. Light that is absorbed by the photovoltaic cells is light that would otherwise pass through the window 24, adding heat to the building which may have to be removed by air conditioning. The lens block assembly also may block light at high angles, which eliminates or otherwise mitigates the need for louvers. For example, louvers are particularly popular generally southern facing windows in the northern hemisphere to reduce air conditioning loads and increase comfort for building occupants. The lens block assembly may be supported by brackets attached to the building's exterior walls (not shown).

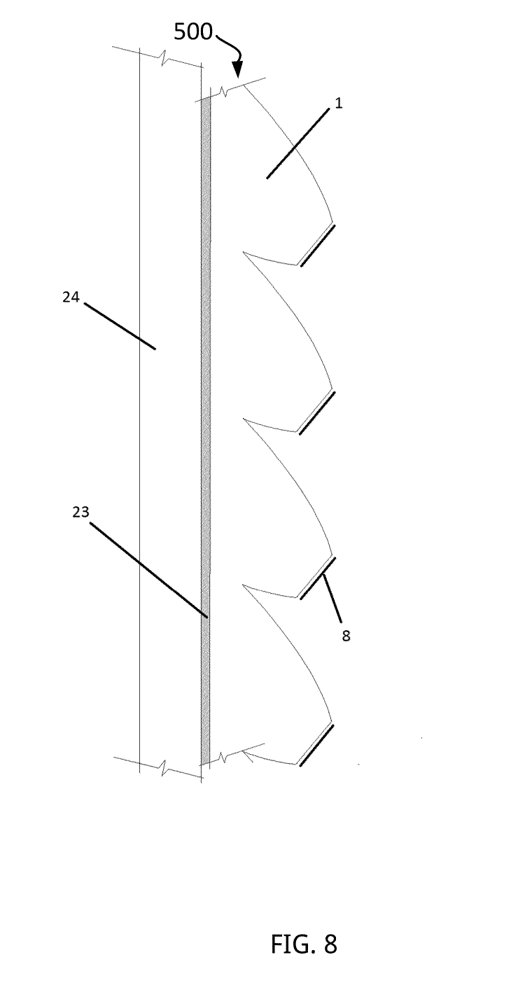

FIG. 8 shows a cross-sectional view of a lens block 500, or an assembly of lens blocks 500, adhered to the inside of a window 24, and adhered by coupling medium 23. The coupling medium 23 adheres to the window and allows for differential thermal expansion. As lens blocks 500 may be adhered to a window 24 individually, the coupling medium 23 may able to accommodate differential thermal expansion between the window and lens block whereas the greater thermal expansion occasioned by larger structures may exceed the ability of the coupling medium 23 to have sufficient elasticity to accommodate the expansion. As noted below, coupling medium 23 may be a silicone gel, such as is made by the Dow Corning Corporation.

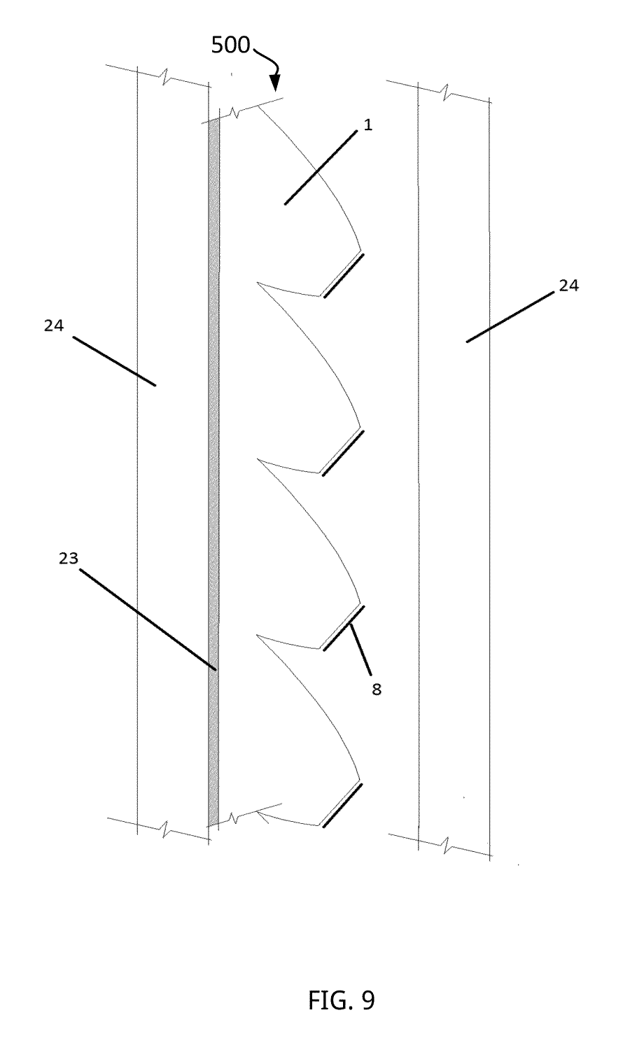

FIG. 9 is a sectional representation of a lens block 500, or an assembly of a lens blocks 500, constructed in the inside of a multiple pane thermal window. The lens block 500 may be applied to the outermost pane in a similar manner to that described above. To prevent out-gassing of water vapor and subsequent condensation, the polymer material may be dried prior to incorporation within the multiple pane window.

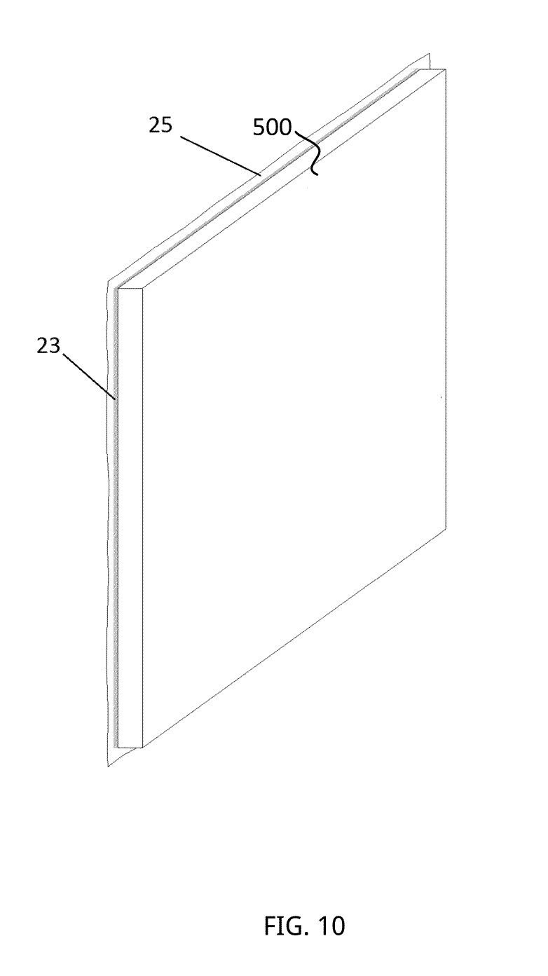

FIG. 10 is a perspective view of a lens block 500 with a adhering and lens block coupling medium 23 pre-applied to a lens block for subsequent application to the inside surface of a window. The lens block adhering and coupling medium 23 may have many of the characteristics of the coupling medium 23 used between a concentrating lens 1 and photovoltaic strip 8, namely the ability to optically couple or wet surfaces, allow for differential thermal expansion, have high optical clarity, exhibit refractive indices similar to those of both the window and contiguous outward pane 2, and provide adhesive strength to hold and maintain the lens block in place to the window. One particular adhesive well suited is the Dow Corning silicone gel Sylgard 527.

In order to prevent inadvertent contact or contamination by foreign surfaces, the lens block coupling medium 23 layer may be protected by temporary application of a film over the medium. The protective film 25 may be polyethylene terephthalate (PET), or other suitable films. Prior to the application of the lens block to a window, the protective film 25 may be peeled off.

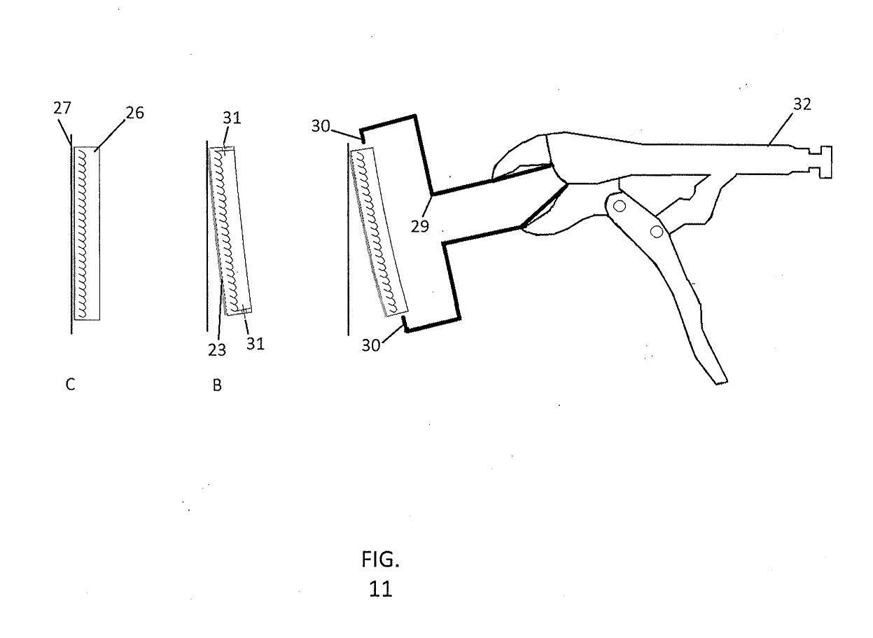

FIG. 11 illustrates a method for applying a lens block to the inside of a window, and a tool for performing the same, in accordance with an embodiment of the present disclosure. It should be appreciated that air bubbles may be trapped between the window and the lens block coupling medium 23 during coupling. Air bubbles do not provide optical coupling, may increase reflective losses, and may reduce the amount of light reaching the photovoltaic target. Moreover, air bubbles may also adversely affect the aesthetic appearance of an installation.

Bending the lens block 500 slightly allows the air bubbles to be squeezed out and results in a complete or otherwise suitable contact with the window. A tool, such as tool 29, may be used to temporarily attach to the lens block. This may be a custom designed tool, or may be simply constructed by welding plates 29 or rods such as may be constructed from steel to locking pliers 32, often referred to by the brand name Vice Grips. In this embodiment pins 30 attached to the plates 29 may be inserted into holes 31 in the side walls of the lens blocks. Instead of pins and holes, a similar result may be achieved by having the edges of the plates 29 inserted in indentations or grooves in the outside of the lens block side walls.

Sequence A, B and C shown in FIG. 11 demonstrate one example method of application of a lens block using a bending tool. Only a slight bend may be necessary; the bend has been exaggerated in the drawing to illustrate the concept.

When the handles of application tool, in this case the locking pliers 32, are squeezed together, a bend is imparted to the lens block, as depicted in Sequence A. One edge of lens block, in this case the top edge, is placed in contact with the window. Sequence B represents the lens block when pressure on the handles of the application tool is eased, flattening the lens block and bringing more of the lens block coupling medium 23 in contact with the window 24. Sequence C represents the lens block and its coupling medium in complete contact with the window after the application tool has been completely released.

By this application technique, the progressively increasing contact from one edge of the lens block to the opposite edge provides a path for air to escape as the lens block is applied to the window, preventing the formation of bubbles.

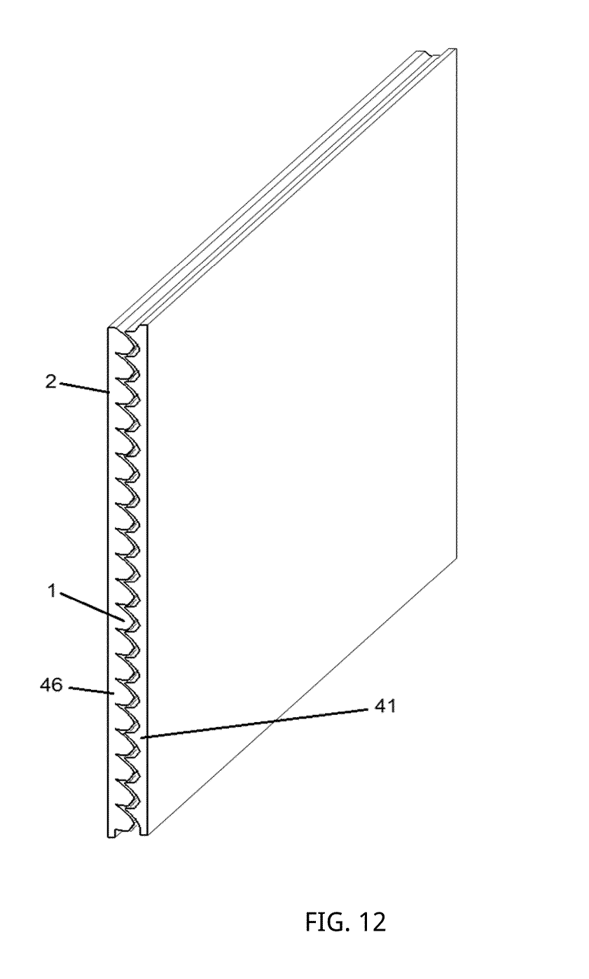

FIG. 12 shows a three-dimensional representation of a concentrating lens block with contiguous outward pane 2 and concentrating lenses 1, in proximity to transparency coupling block 41 or optical coupling block, in accordance with an embodiment of the present disclosure. The profile of transparency coupling block 41 may be formed to substantially conform to the profile of the concentrating lens block 46 and its concentrating lenses 1.

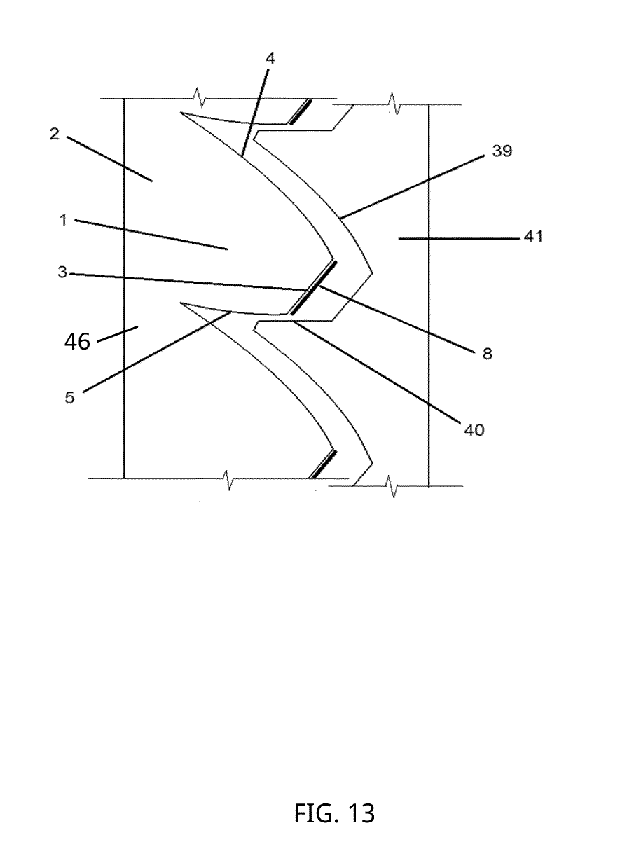

Turning attention now to FIG. 13, which shows a cross-sectional view of concentrating lens block 46 adjacent to transparency coupling block 41 with a space separating them. Transparency coupling block 41 may be made from materials similar to those of the concentrating lens block 46, such as PMMA, polycarbonate, or other transparent plastics or glass, for example. It may also be made of clear urethane rubber, such as ClearFlex made by the Smooth-On Corporation. The material of profile surface of the transparent coupling block 41 may have a refractive index of 95% to 105% of the refractive index of the material of the concentrating lens block 46 to minimize reflective losses due to transitioning through materials of differing refractive indices. The material of the profile surface of the transparent coupling block 41 may have a surface energy with respect to that of the material of the concentrating lens block 46 to allow wetting or optical coupling between the two surfaces when the concentrating lens block 46 and the transparency coupling block 41 are brought into contact with each other.

The surface material of the transparency coupling block 41 may be a film of clear urethane rubber or similar transparent material having the requisite surface tension with respect to the material of the concentrating lens block, although other embodiments will be apparent in light of this disclosure.

Alternatively, or in addition, the concentrating lens block 46 may have a film of clear urethane rubber or clear material with the requisite surface tension to effect optical coupling with the transparency coupling block, or may be made entirely out of such material.

Continuing with FIG. 13, curved surface 39 of transparent coupling block 41 may be formed to substantially match the shape of lens surface 4 of the concentrating lens 1. Additionally, surface 40 of the transparent coupling block 41 may be formed to substantially match the shape of surface 5 of the concentrating lens 1, or may be made substantially flat to allow for unrestricted movement between the lens block and the coupling block.

The intersection of curves 39 and 40 may be truncated to avoid dimensional tolerance or interference issues when the lens block and coupling block are brought into contact. Further, surface 40 of the transparency block may be recessed to accommodate the space needed by the photovoltaic strip 8, its optical coupling material and electrical wiring.

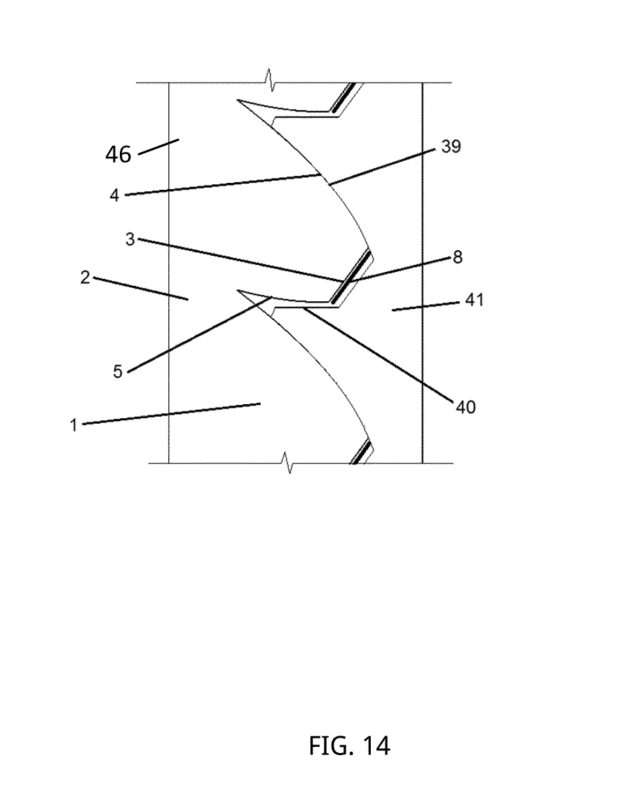

FIG. 14 is shows a cross-sectional view of a lens block 46 and transparency coupling block 41 in direct contact or otherwise positioned in close proximity with each other. Because of the fit of curved surface 4 of the lens block and curved surface 39 of the transparency coupling block, the relative surface energies between the material of the surfaces and the comparable refractive indices, the two blocks in contact may obviate the total internal reflection that would have otherwise occurred in the concentrating lenses 1. The result is that light may then pass through the two blocks as if it were one monolithic pane of transparent material.

Thus the coupling block 41 can provide a light emitting surface configured to emit light received via an optical coupling with the lens block 46. Thus, the photovoltaic device may provide transparency that allows an observer to at least partially view objects there through. In particular, the objects may be visible based on the light incident surface receiving light wavelengths provided or reflected by the objects, and the light incident surface passing those wavelengths to the light emitting surface of the coupling block 41. The angle of incidence associated with the light wavelengths received by the light incident interface and passed to the light emitting surface may be generally equal to, or less than, a critical angle of the material the light incident interface is made of.

Some light may hit the photovoltaic strips 8, and if surface 40 of the transparency block is modified to allow relative movement between the two blocks, the gap and interface between surfaces 5 and 40 may cause some light to be refracted. However, given the substantial surface area of surfaces 4 and 39, a substantial portion of light passing in either direction through the contacted blocks may not substantially refract and thus will be transparent.

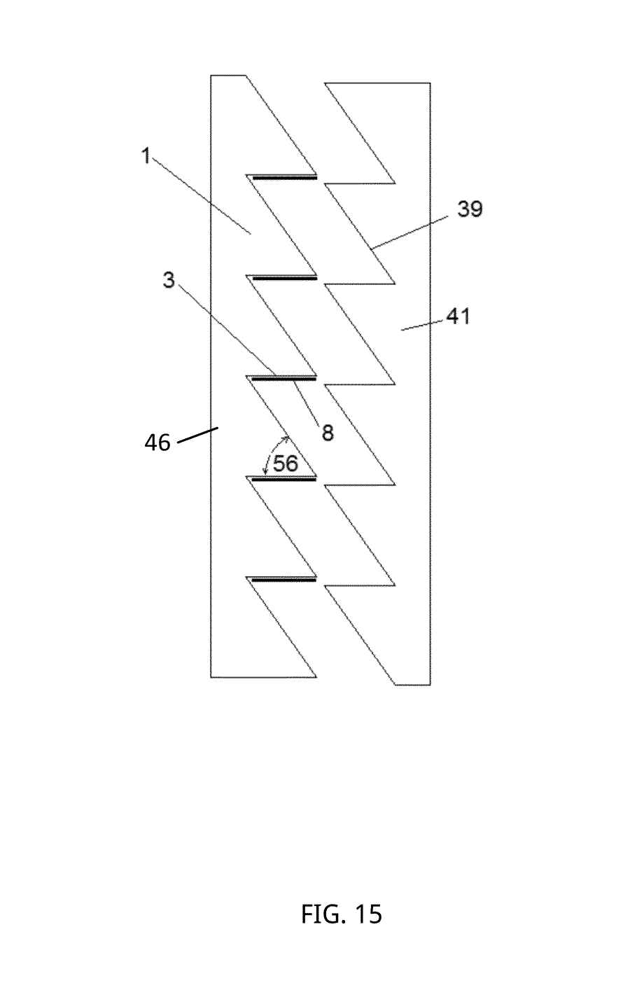

FIG. 15 is a cross-sectional view of a concentrating lens block 46 and a transparency coupling block 41, both with triangular or wedged-shaped lens geometries, in juxtaposition, in accordance with an embodiment of the present disclosure. As in the embodiments previously described, the concentrating lens block 46 comprises a plurality of concentrating lenses 1, with each lens 1 having a target surface 3 which is optically coupled to photovoltaic strip 8.

Angle 56 represents the angle between the reflecting surface 4 and its adjoining target surface 3 of each lens 1. One particular range for angle 56 that allows each lens 1 to harvest sunlight while maintaining a suitable level of concentration in order to minimize the amount of necessary photovoltaic cell material is 40 to 65 degrees, for example.

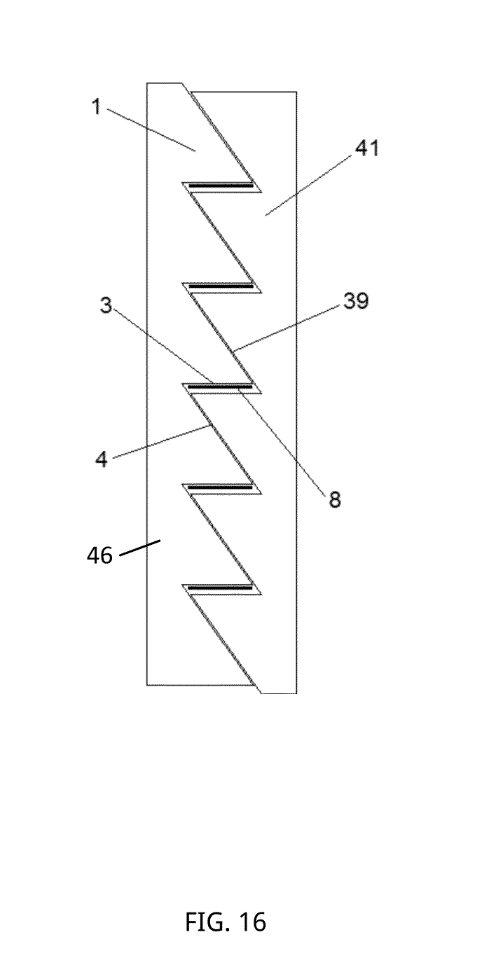

FIG. 16 is a cross-sectional view of a concentrating lens block 46 and a transparency coupling block 41, both configured with triangular or wedge-shaped lenses, in contact such that lens surface 4 of the concentrating lens block and mating surface 39 of the transparency coupling block are in contact, becoming optically coupled via the mechanisms described previously. As in embodiments previously described, the optical coupling of the blocks eliminates the difference in refractive indices between materials and internal reflections that might otherwise occur. The result is a monolithic optical assembly similar to a pane of glass or velar polymer, and may advantageously provide transparency in both directions.

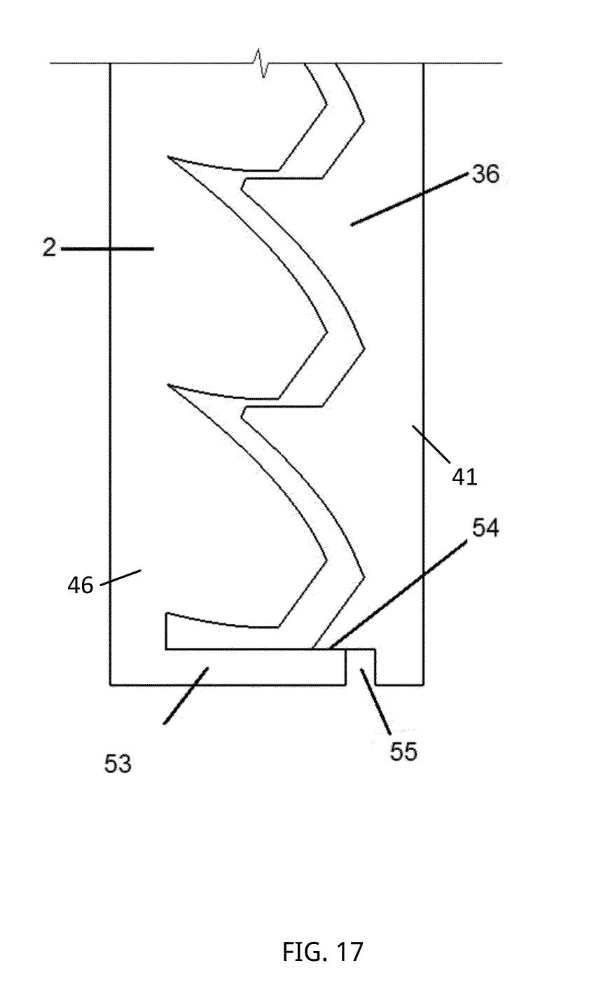

FIG. 17 is a perspective view of the bottom portion of a concentrating lens block 46 and a transparency coupling block 41 in juxtaposition. In this embodiment, lens block 46 incorporates a shelf or lip 53 that may serve to support transparency coupling block 41. Coupling block 41 in turn may incorporate a flat surface 54 that allows it to “slide” on shelf 42 and rest thereon, allowing relative horizontal movement between the two blocks. Space 54 may be used so that there limited restriction of horizontal movement by the shelf 53 of the lens block 46 and transparency block 41.

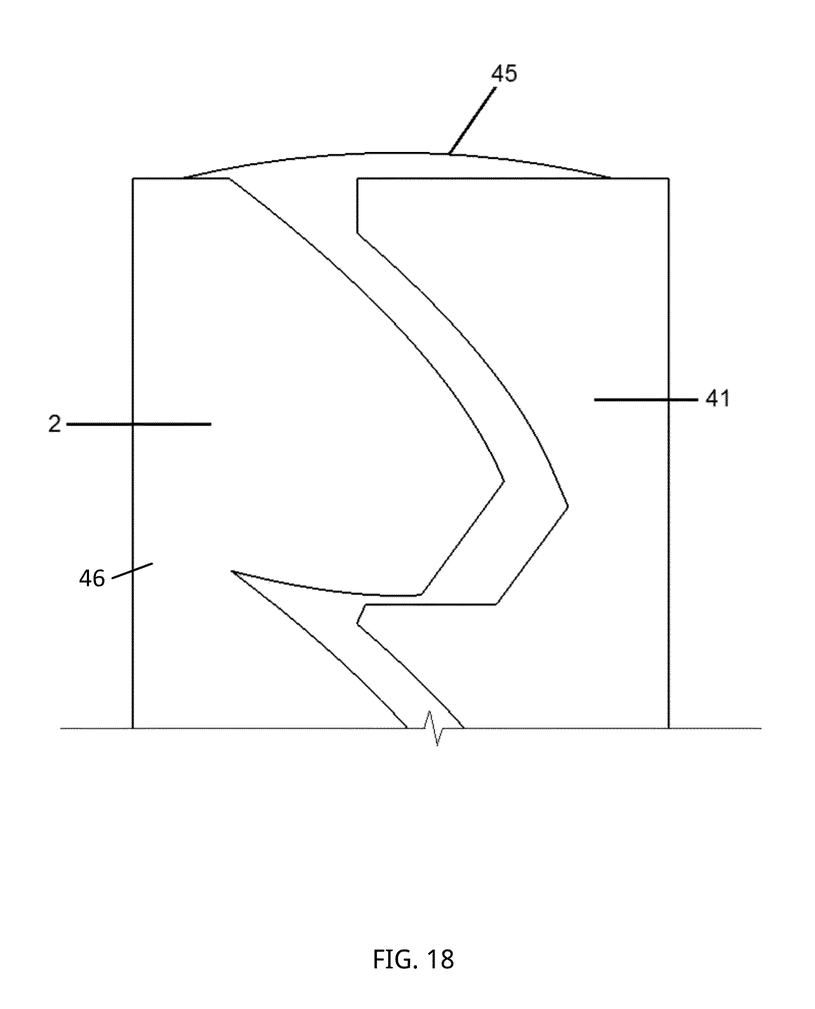

FIG. 18 shows a cross-sectional view of a top portion of a lens block 46 and a coupling block 41 in juxtaposition. Membrane 45, which may be made from a transparent film such as, for example, PMMA, PET, plastic or other film material may serve to seal all edges of the lens block and transparency block, or groups of blocks, such that the space between the two blocks is hermetically sealed. Membrane 45 may also serve as a support for transparency block 41 and my assist in keeping the blocks in the relative position necessary to effect engagement and disengagement. It may also have an inherent spring force to assist in disengaging concentrating lens block 46 and transparency coupling block 41. This support may be in place of or in addition to the support provided by shelf 42 of FIG. 17.

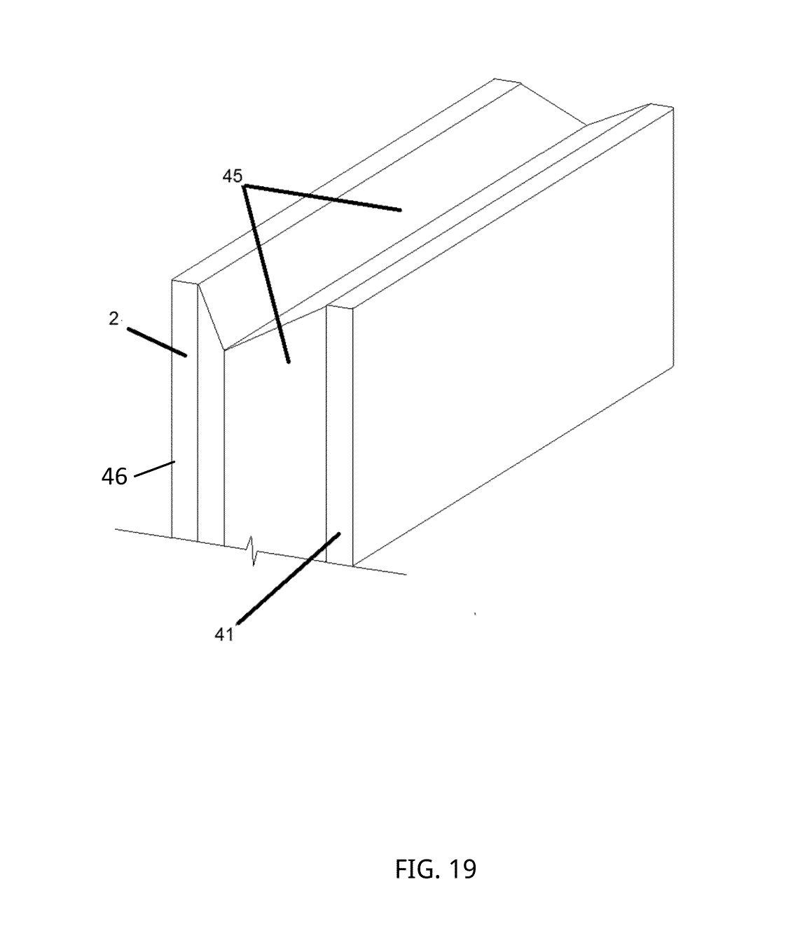

FIG. 19 is shows a partial three-dimensional representation of concentrating lens block 46 and transparency coupling block 41 connected on two sides by membrane 45, in accordance with an embodiment of the present disclosure. To be hermetically sealed, membrane 40 may be attached to all four edges of lens block 46 and transparency block 36 with an adhesive.

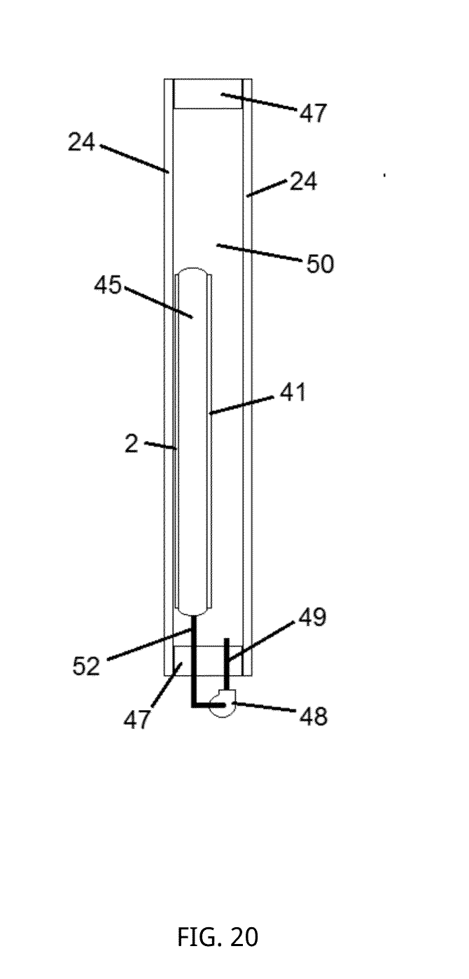

FIG. 20 is a schematic sectional drawing of an embodiment of the present disclosure including a mechanism to engage and disengage contact between lens block 46 and transparency coupling block 41. The lens block 46 and transparency coupling block 41 are shown connected by membrane 45 inside an insulated glass window unit, characterized by window panes 24 separated on all four sides by widow spacer 47.

As in the previous embodiments, contiguous outer pane 2 may be coupled to the inner surface of the outer pane 24 by coupling medium 23. In this embodiment, tube 52 connects through an opening in membrane 45 to the space between concentrating lens block 46 and transparency coupling block 41. Also in this embodiment, tube 52 passes through window spacer 47 to pneumatic pressure device 48. Pneumatic pressure device 48 may be a fan, blower, vacuum pump or central pneumatic air system, the effect of which is create a pressure difference between the space between the two blocks and the interior of the insulated glass window 50. The pneumatic device, when creating the differential air pressure, may be activated by a switch, building automation system or other control such that the blocks can be engaged making them transparent to an observer and producing electrical power from light incident on the photovoltaic strips. When pneumatic device 48 is turned off, the lens blocks may become disengaged, allowing lenses 1 of the lens block 46 to direct light to the photovoltaic strips 8, allowing for full power and scrambling the light not directed to the strips to effect privacy and allowing translucent daylighting.

### Further Example Embodiments

An embodiment of the present disclosure includes a photovoltaic device for concentrating light onto a photovoltaic target. The photovoltaic device may comprise a base having a light incident interface, a lens extending from the base and having a lens body, the lens body including a first surface extending away from the base at generally a first acute angle relative to the base, and a collector surface extending from a distal end of the first surface toward the base at generally a second angle, wherein the collector surface includes a photovoltaic target configured to receive light reflected from the first surface and to convert the received light into electrical energy.

In one aspect, the base may be made of a material having a refractive index of about 1.5. In another aspect, the light incident interface may comprise a generally transparent material. In yet another aspect, the first surface may follow a generally parabolic curve.

In one aspect, the lens may comprise a parabolic compound concentrator. In another aspect, the lens may include an aperture defined by a length L along the base, and the lens may further include a width W defined by a length of the collector surface, and wherein a ratio of length L to width W may be 2.9 to 1.

In one aspect, the lens may comprise an optical coupling block, the optical coupling block may include at least one transparent surface, the at least one transparent surface defining a recess configured to generally compliment a shape of the lens body and receive an apex formed by an intersection of the first surface and the collector surface. In this aspect, the lens may be optically coupled to the optical coupling block based in part on the recess receiving the apex of the lens body and allowing a substantial portion of the first surface and the collector surface to make contact or otherwise be in close proximity with the at least one transparent surface of the optical coupling block. Further in this aspect, the lens may be optically coupled to the optical coupling block based in part on a transparent adhesive. Still further in this aspect, the optical coupling block may be configured to receive light passed from the lens based in part on the received light arriving at the light incident interface at an angle of incidence generally equal to or less than the critical angle of a material of the light incident interface.

In one aspect, the lens and optical coupling block may collectively form a monolithic structure that provides transparency similar to a pane of glass. In this aspect, the optical coupling block may further include a light emitting surface configured to emit light received via an optical coupling with the lens, and wherein the photovoltaic device may provide transparency that allows an observer to at least partially view objects there through, the objects being visible based on the light incident surface receiving light wavelengths provided or reflected by the objects and the light incident surface passing those wavelengths to the light emitting surface of the optical coupling block. Further, the an angle of incidence associated with the light wavelengths received by the light incident interface and passed to the light emitting surface may generally be equal to, or less than, a critical angle of the material the light incident interface is made of.

In another aspect, a window installed on a vertical or generally vertical surface of a building and may comprise the photovoltaic device, wherein the photovoltaic device may be disposed between window panes.

In another aspect of the present disclosure, a window-mounted thermal management device is disclosed. The window-mounted thermal management device may include a plurality of concentrating lenses extending from a common light incident interface and configured to receive and internally reflect light having an angle of incidence generally greater than a first angle to a mirrored surface within each respective concentrating lens, and to pass light having an angle of incidence generally equal to or less than the first angle.

In yet another aspect of the present disclosure, a window-mounted photovoltaic device is disclosed. The window-mounted photovoltaic device may comprise a plurality of concentrating lenses extending from a common light incident interface, each concentrating lens may comprise a lens body, the lens body including a first surface extending away from the base at generally a first acute angle relative to the base, and a collector surface extending from a distal end of the first surface toward the base at generally a second angle, wherein the collector surface includes a photovoltaic target configured to receive light reflected from the first surface and convert the received light into electrical energy.

In one aspect, the window-mounted photovoltaic device may further comprise an optical coupling block, the optical coupling block may include a plurality recesses formed along a first side, wherein the recesses may be shaped to generally compliment the plurality of concentrating lenses and provide optical coupling thereto.

In one aspect, the optical coupling block may be made of a material having an index of refraction generally matching the index of refraction associated with materials of the concentrating lenses, wherein the recesses and the matched index of refraction allow the optical coupling block to optically couple to the plurality of concentrating lenses. In another aspect, the optical coupling block may be configured to receive light passed from the plurality of concentrating lenses based in part on the received light arriving at the common light incident interface at an angle of incidence generally equal to or less than the critical angle of a material of the common light incident interface.

In one aspect, the optical coupling block may further include a light emitting surface, the light emitting surface being disposed on a side opposite the recesses of the optical coupling block and configured to emit light received via an optical coupling with the plurality of concentrating lenses, and wherein the photovoltaic device provides transparency that allows an observer to at least partially view objects there through, the objects being visible based on the common light incident surface receiving light wavelengths provided or reflected by the objects and the light incident surface passing those wavelengths to the light emitting surface of the optical coupling block.

In one aspect, the window-mounted device may be configured to be mounted between adjacent glass panes of a window. In another aspect, the plurality of concentrating lenses may refract at least a portion of incident light in multiple different angles to provide one-way transparency, the one-way transparency substantially obscuring from view objects located proximal to a side of the window-mounted photovoltaic device opposite the common light incident interface.

The foregoing description of the exemplary embodiments of this disclosure has been presented for the purposes of illustration and description. It is not intended to be exhaustive or to limit the disclosure to the precise form disclosed. Many modifications and variations are possible in light of this disclosure. It is intended that the scope of the disclosure not be limited not by this detailed description, but rather by the claims appended hereto.

What is claimed is:

1. A photovoltaic device for concentrating light onto a photovoltaic target, the photovoltaic device comprising:
a base having a light incident interface;
a lens extending from the base and having a lens body, the lens body including a first surface extending away from the base at generally a first acute angle relative to the base, and a collector surface extending from a distal end of the first surface toward the base at generally a second angle, wherein the collector surface includes a photovoltaic target configured to receive light reflected from the first surface and to convert the received light into electrical energy.

2. The photovoltaic device of claim 1, wherein the base is made of a material having a refractive index of about 1.5.

3. The photovoltaic device of claim 1, wherein the light incident interface comprises a generally transparent material.

4. The photovoltaic device of claim 1, wherein the first surface follows a generally parabolic curve.

5. The photovoltaic device of claim 1, wherein the lens comprises a parabolic compound concentrator.

6. The photovoltaic device of claim 1, wherein the lens includes an aperture defined by a length L along the base, and the lens further includes a width W defined by a length of the collector surface, and wherein a ratio of length L to width W is 2.9 to 1.

7. The photovoltaic device of claim 1, further comprising an optical coupling block, the optical coupling block including at least one transparent surface, the at least one transparent surface defining a recess configured to generally compliment a shape of the lens body and receive an apex formed by an intersection of the first surface and the collector surface.

8. The photovoltaic device of claim 7, wherein the lens is optically coupled to the optical coupling block based in part on the recess receiving the apex of the lens body and allowing a substantial portion of the first surface and the collector surface to make contact or otherwise be in close proximity with the at least one transparent surface of the optical coupling block.

9. The photovoltaic device of claim 7, wherein the lens is optically coupled to the optical coupling block based in part on a transparent adhesive.

10. The photovoltaic device of claim 7, wherein the optical coupling block is configured to receive light passed from the lens based in part on the received light arriving at the light incident interface at an angle of incidence generally equal to or less than the critical angle of a material of the light incident interface.

11. The photovoltaic device of claim 7, wherein the lens and optical coupling block collectively form a monolithic structure that provides transparency similar to a pane of glass.

12. The photovoltaic device of claim 7, wherein the optical coupling block further includes a light emitting surface configured to emit light received via an optical coupling with the lens, and wherein the photovoltaic device provides transparency that allows an observer to at least partially view objects there through, the objects being visible based on the light incident surface receiving light wavelengths provided or reflected by the objects and the light incident surface passing those wavelengths to the light emitting surface of the optical coupling block.

13. The photovoltaic device claim 12, wherein an angle of incidence associated with the light wavelengths received by the light incident interface and passed to the light emitting surface is generally equal to, or less than, a critical angle of the material the light incident interface is made of.

14. A window installed on a vertical or generally vertical surface of a building and comprising the photovoltaic device of claim 1, wherein the photovoltaic device is disposed between window panes.

15. A window-mounted thermal management device comprising:
a plurality of concentrating lenses extending from a common light incident interface and configured to receive and internally reflect light having an angle of incidence generally greater than a first angle to a mirrored surface within each respective concentrating lens, and to pass light having an angle of incidence generally equal to or less than the first angle.

16. A window-mounted photovoltaic device, the window-mounted photovoltaic device comprising:
a plurality of concentrating lenses extending from a common light incident interface, each concentrating lens comprising:
a lens body, the lens body including a first surface extending away from the base at generally a first acute angle relative to the base, and a collector surface extending from a distal end of the first surface toward the base at generally a second angle, wherein the collector surface includes a photovoltaic target configured to receive light reflected from the first surface and convert the received light into electrical energy.

17. The window-mounted photovoltaic device 15, further comprising an optical coupling block, the optical coupling block including a plurality recesses formed along a first side, wherein the recesses are shaped to generally compliment the plurality of concentrating lenses and provide optical coupling thereto.

18. The window-mounted photovoltaic device of claim 16, wherein the optical coupling block is made of a material having an index of refraction generally matching the index of refraction associated with materials of the concentrating lenses, wherein the recesses and the matched index of refraction allow the optical coupling block to optically couple to the plurality of concentrating lenses.

19. The window-mounted photovoltaic device of claim 16, wherein the optical coupling block is configured to receive light passed from the plurality of concentrating lenses based in part on the received light arriving at the common light incident interface at an angle of incidence generally equal to or less than the critical angle of a material of the common light incident interface.

20. The window-mounted photovoltaic device of claim 16, wherein the optical coupling block further includes a light emitting surface, the light emitting surface being disposed on a side opposite the recesses of the optical coupling block and configured to emit light received via an optical coupling with the plurality of concentrating lenses, and wherein the photovoltaic device provides transparency that allows an observer to at least partially view objects there through, the objects being visible based on the common light incident surface receiving light wavelengths provided or reflected by the objects and the light incident surface passing those wavelengths to the light emitting surface of the optical coupling block.
